(19) United States
(12) Patent Application Publication
(10) Pub. No.: US 2026/0147279 A1
(43) Pub. Date: May 28, 2026

(54) DEVELOPER COMPOSITION FOR METAL-CONTAINING PHOTORESIST, AND METHOD OF FORMING PATTERNS INCLUDING DEVELOPING METHOD USING THE COMPOSITION

(71) Applicant: SAMSUNG SDI CO., LTD., Yongin-si (KR)

(72) Inventors: Jongpil HO, Suwon-si (KR); Hyungrang MOON, Suwon-si (KR); Seung HAN, Suwon-si (KR); Taeho KIM, Suwon-si (KR); Gyeonghun PARK, Suwon-si (KR); Rosa SHIN, Suwon-si (KR); Si-Kyun PARK, Suwon-si (KR); Taeksoo KWAK, Suwon-si (KR)

(21) Appl. No.: 19/331,333

(22) Filed: Sep. 17, 2025

(30) Foreign Application Priority Data
Oct. 2, 2024 (KR) 10-2024-0134186

(51) Int. Cl. G03F 7/32; G03F 7/004; G03F 7/38

(52) U.S. Cl. CPC G03F 7/325; G03F 7/0042; G03F 7/38

(57) ABSTRACT

A developer composition for a metal-containing photoresist and a pattern forming method including a developing method utilizing the developer composition are disclosed. For the coordinate x, as specified by the Hansen solubility parameters (δd, δp, and δh) of the developer composition, a solubility radius Rₐ with a coordinate a as a center value and a solubility radius R_{b} with a coordinate b as a center value may be calculated, and a distance (x̅ a̅) between the coordinate x and the coordinate a and a distance (x̅ b̅) between the coordinate x and the coordinate b, calculated by Equations 1 and 2, respectively, may have the relationships x̅ a̅<Rₐ and x̅ b̅>R_{b}.

$$\overline{x {a}^{2}} = 4 {( δ {d}_{x} - δ {d}_{a} )}^{2} + {( δ {p}_{x} - δ {p}_{a} )}^{2} + {( δ {h}_{x} - δ {h}_{a} )}^{2} \qquad Equation 1$$

$$\overline{x {b}^{2}} = 4 {( δ {d}_{x} - δ {d}_{b} )}^{2} + {( δ {p}_{x} - δ {p}_{b} )}^{2} + {( δ {h}_{x} - δ {h}_{b} )}^{2} \qquad Equation 2$$

### CROSS-REFERENCE TO RELATED APPLICATION

The present application claims priority to and the benefit of Korean Patent Application No. 10-2024-0134186, filed on Oct. 2, 2024, at the Korean Intellectual Property Office, the entire disclosure of which is incorporated herein by reference.

### BACKGROUND

### 1. Field

One or more embodiments of the present disclosure relate to a developer composition for a metal-containing photoresist and a method of forming or providing patterns including a developing method utilizing the developer composition.

### 2. Description of the Related Art

The semiconductor industry has undergone a continuous reduction of critical dimensions, and, for this dimensional reduction, it is desirable to develop new types or kinds of high-performance photoresist materials and a patterning method that is suitable for processing and patterning with increasingly smaller features.

Chemically amplified (CA) photoresists are designed to secure high sensitivity, but because an elemental makeup thereof (e.g., in smaller quantities of oxygen (O), fluorine (F), sulfur(S), and/or carbon (C)) lowers absorbance at a wavelength of about 13.5 nm and, as a result, reduces sensitivity, the photoresists may suffer more difficulties partially under the extreme ultraviolet (EUV) exposure. Also, the CA photoresists may have difficulties due to roughness issues in small feature sizes, and due partially to the nature of acid catalyst processes, line edge roughness (LER) experimentally turns out to increase as a photospeed decreases. Due to these drawbacks and problems of the CA photoresist, a new type or kind of high-performance photoresists is required or desired in the semiconductor industry.

For example, it is necessary or desirable to develop a photoresist securing excellent or suitable etching resistance and resolution and concurrently (e.g., simultaneously), improving or enhancing sensitivity and enhancing critical dimension (CD) uniformity and LER characteristics in the photolithography process.

### SUMMARY

One or more aspects of embodiments of the present disclosure are directed toward a developer composition for a metal-containing photoresist.

One or more aspects of embodiments of the present disclosure are directed toward a method of forming or providing patterns including a developing method utilizing the developer composition.

Additional aspects of embodiments will be set forth in part in the description which follows and, in part, will be apparent from the description or may be learned by practice of the presented embodiments of the disclosure.

A developer composition applied to a metal-containing photoresist according to one or more embodiments includes,
a coordinate a, which is specified by the Hansen solubility parameters (δd, δp, and δh) of a first photoresist exposed to the metal-containing photoresist with a first exposure energy of 9 mJ/cm² to 12 mJ/cm²;
a coordinate b, which is specified by the Hansen solubility parameters (δd, δp, and δh) of a second photoresist exposed to the metal-containing photoresist with a second exposure energy that is 5 mJ/cm² to 10 mJ/cm² higher than the first exposure energy; and
for a coordinate x which is specified by the Hansen solubility parameters (δd, δp, and δh) of the developer composition,
a solubility radius Rₐ with the coordinate a as a center value is calculated,
a solubility radius R_{b} with the coordinate b as a center value (e.g., an other center value) is calculated, and
a distance (x̅ a̅) between the coordinate x and the coordinate a and a distance (x̅ b̅) between the coordinate x and the coordinate b, which are calculated by Equation 1 and Equation 2, respectively, have
the relationships x̅ a̅<Rₐ and x̅ b̅>R_{b}.

$$\overline{x {a}^{2}} = 4 {( δ {d}_{x} - δ {d}_{a} )}^{2} + {( δ {p}_{x} - δ {p}_{a} )}^{2} + {( δ {h}_{x} - δ {h}_{a} )}^{2} \qquad Equation 1$$

$$\overline{x {b}^{2}} = 4 {( δ {d}_{x} - δ {d}_{b} )}^{2} + {( δ {p}_{x} - δ {p}_{b} )}^{2} + {( δ {h}_{x} - δ {h}_{b} )}^{2} \qquad Equation 2$$

The Hansen Solubility Parameter (HSP), solubility radius Rₐ, and solubility radius R_{b} may be predicted using the Generate Hansen Parameters module of the COSMOquick version 22 program.

A method of forming or providing patterns according to one or more embodiments includes coating a metal-containing photoresist composition on a substrate, performing heat treatment in which a metal-containing photoresist film is formed or provided on the substrate by drying and heating, exposing the metal-containing photoresist film, and developing utilizing the developer composition for the metal-containing photoresist.

The developer composition applied to a metal-containing photoresist according to one or more embodiments may be a developer composition having specific (e.g., set or predetermined) Hansen solubility parameters derived through simulation, and by applying a developer composition satisfying the elements as described in one or more embodiments, the solubility of an unexposed portion may be increased or enhanced and the solubility of an exposed portion may be decreased, thereby improving or enhancing the contrast in solubility between the unexposed and exposed portions, thereby enabling the implementation of a photoresist pattern in which the occurrence of scum and bridges is significantly reduced while maintaining excellent or suitable sensitivity.

### BRIEF DESCRIPTION OF THE DRAWINGS

The above and other aspects and features of certain embodiments of the present disclosure will become more apparent from the following description taken in conjunction with the accompanying drawings.

FIGS. 1A-1C are cross-sectional views illustrating a process sequence in order to describe a method of forming or providing patterns.

FIG. 2 is a schematic view illustrating the solubility range of each photoresist according to exposure energy by performing a simulation on a composition according to one or more embodiments of the present disclosure.

### DETAILED DESCRIPTION

Hereinafter, the subject matter of the present disclosure will be described in more detail with reference to the accompanying drawings. In the following description of the present disclosure, the functions or constructions that are generally understood by a person of ordinary skill in the art may not be described in order to clarify the present disclosure.

The utilization of “may” if (e.g., when) describing embodiments of the present disclosure refers to “one or more embodiments of the present disclosure.”

As used herein, the singular forms “a,” “an,” and “the” are intended to include the plural forms as well, unless the context clearly indicates otherwise. The singular expression includes the plural expression unless the context clearly dictates otherwise.

As used herein, the term “and/or” or “or” includes any and all combinations of one or more of the associated listed items.

Throughout the present disclosure, the expressions, such as “at least one of,” “one of,” and “selected from,” if (e.g., when) preceding a list of elements, modify the entire list of elements and do not modify the individual elements of the list. For example, “at least one of a, b, or c,” “at least one selected from among a, b, and c,” “at least one selected from among a to c,” and/or the like indicates only a, only b, only c, both (e.g., simultaneously) a and b, both (e.g., simultaneously) a and c, both (e.g., simultaneously) b and c, all of a, b, and c, or variations thereof.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

In the context of the present application and unless otherwise defined, the terms “use,” “using,” and “used” may be considered synonymous with the terms “utilize,” “utilizing,” and “utilized,” respectively.

As utilized herein, the terms “substantially,” “about,” or similar terms are used as terms of approximation and not as terms of degree and are intended to account for the inherent deviations in measured or calculated values that would be recognized by those of ordinary skill in the art. “About” as used herein is inclusive of the stated value and refers to as being within an acceptable range of deviation for the particular value as determined by one of ordinary skill in the art, considering the measurement in question and the error associated with measurement of the particular quantity (e.g., the limitations of the measurement system). For example, “about” may refer to as being within one or more standard deviations or within ±30%, ±20%, ±10%, or ±5% of the stated value. Also, it should be understood that, even if (e.g., when) the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

In order to clearly illustrate the present disclosure, the description and relationships may not be provided, and throughout the disclosure, substantially the same or similar configuration or arrangement elements may be designated by the same reference numerals. Also, because the size and thickness of each configuration or arrangement illustrated in the drawing are arbitrarily shown for better understanding and ease of description, embodiments of the present disclosure are not necessarily limited thereto.

In the drawings, the thickness of layers, films, panels, regions, and/or the like may be exaggerated for clarity. In the drawings, the thickness of a part of layers, regions, and/or the like may be exaggerated for better understanding and ease of description.

It will be understood that if (e.g., when) an element, such as a layer, a film, a region, or a substrate, is referred to as being “on” or “above” another element, it may be directly on or directly above the other element or intervening elements may also be present therebetween. In contrast, if (e.g., when) an element is referred to as being “directly on” or “directly above” another element, there are no intervening elements present therebetween.

Herein, the Hansen Solubility Parameter (HSP) is a value used to predict the solubility of a material. The Hansen solubility parameter may reflect the physicochemical dissolution properties, also referred to as the dissolution capability, of organic materials. HSP is based on the concept that “two materials having similar intermolecular interactions are likely to dissolve in each other.”

The Hansen solubility parameters may be calculated according to the approach proposed by Charles Hansen in “Hansen Solubility Parameters: A user's handbook,” Second Edition (2007) Boca Raton, Fla.: CRC Press. ISBN 978-0-8493-7248-3. According to this approach, three parameters δd, δp, and δh, referred to as “Hansen parameters,” are sufficient or suitable to predict the solvent behavior for a given molecule. At MPa^{1/2}, the parameter δd may quantify the energy of the dispersion forces between molecules, for example, van der Waals forces. At MPa^{1/2}, the parameter δp may represent the energy of intermolecular dipolar interaction. Also, the parameter δh at MPa^{1/2} may quantify the energy derived from intermolecular hydrogen bonds, for example, the ability to interact via hydrogen bonds.

These three parameters may be considered as coordinates in a three-dimensional space (Hansen space). If (e.g., when) the HSPs of two materials are placed within the Hansen space, the closer the distance between the two points, the more likely they are to dissolve in each other.

Because HSP is a vector quantity, it may rarely have exactly or substantially the same value in pure (e.g., substantially pure) materials. Also, a database has been established for HSPs of materials that are generally used. For this reason, a person skilled in the art may obtain the HSP value of a desired material by referring to the database.

Even if (e.g., when) a material does not have an HSP value registered in the database, the HSP value can be calculated from its chemical structure utilizing computer software, such as COSMOquick.

For example, if (e.g., when) the smiles code of a molecule is entered as input data, the DB value may be predicted if (e.g., when) the HSP of the molecule exists in the COSMOquick DB, and if (e.g., when) it does not exist in the DB, the HSP value of the molecule may be predicted using its own prediction equation.

Hereinafter, a developer composition applied to a metal-containing photoresist according to one or more embodiments is described in more detail.

In a developer composition for a metal-containing photoresist according to one or more embodiments,
a coordinate a, which is specified by the Hansen solubility parameters (δd, δp, and δh) of the first photoresist exposed to the metal-containing photoresist with a first exposure energy of 9 to 12 mJ/cm²;
a coordinate b, which is specified by the Hansen solubility parameters (δd, δp, and δh) of the second photoresist exposed to the metal-containing photoresist with a second exposure energy that is 5 to 10 mJ/cm² higher than the first exposure energy; and
the coordinate x, which is specified by the Hansen solubility parameters (δd, δp, and δh) of the developer composition,
a solubility radius Rₐ with the coordinate a as a center value may be calculated,
a solubility radius R_{b} with the coordinate b as a center value (e.g., an other center value) may be calculated, and
a distance (x̅ a̅) between the coordinate x and the coordinate a and a distance (x̅ b̅) between the coordinate x and the coordinate b, which are calculated by Equation 1 and Equation 2, respectively, may have
the relationships x̅ a̅<Rₐ and x̅ b̅>R_{b}.

$$\overline{x {a}^{2}} = 4 {( δ {d}_{x} - δ {d}_{a} )}^{2} + {( δ {p}_{x} - δ {p}_{a} )}^{2} + {( δ {h}_{x} - δ {h}_{a} )}^{2} \qquad Equation 1$$

$$\overline{x {b}^{2}} = 4 {( δ {d}_{x} - δ {d}_{b} )}^{2} + {( δ {p}_{x} - δ {p}_{b} )}^{2} + {( δ {h}_{x} - δ {h}_{b} )}^{2} \qquad Equation 2$$

The Hansen Solubility Parameter (HSP), solubility radius Rₐ, and solubility radius R_{b} may be predicted using the Generate Hansen Parameters module of the COSMOquick version 22 program.

The Hansen solubility parameter (HSP) is an indicator of the dispersion, polarity, and hydrogen bonding of a material, and is useful to determine compatibility between materials. The solubility between materials is expressed numerically based on the dispersion force (δd), polar force (δp), and hydrogen bonding force (δh) of the materials, and each material is coordinated in three-dimensional space using the δd, δp, and δh factors as axes.

It may be understood that the target photoresist that is dissolved undergoes changes in structure and composition depending on the irradiation with energy, and that these changes also cause changes in the solubility parameter. By differentiating the changing solubility according to the amount of energy irradiated and calculating the Hansen parameter through simulation, it may be feasible to compare the position values of the parameters that change depending on the structural state and components of the material.

By coating the photoresist irradiated with energy to a certain (e.g., set or predetermined) thickness and comparing the thickness after dissolving it utilizing a developer composition as described in one or more embodiments, it may be feasible to determine whether it has been dissolved.

Meanwhile, by calculating the unique (e.g., different) solubility radius (Rₐ, R_{b}) of each material and the distance between the two components (x̅ a̅ and x̅ b̅), the solubility between the two components may be quantified.

At this time, the smaller the distance (x̅ a̅ and x̅ b̅) between the two components in space, the higher the compatibility, for example, solubility, between them.

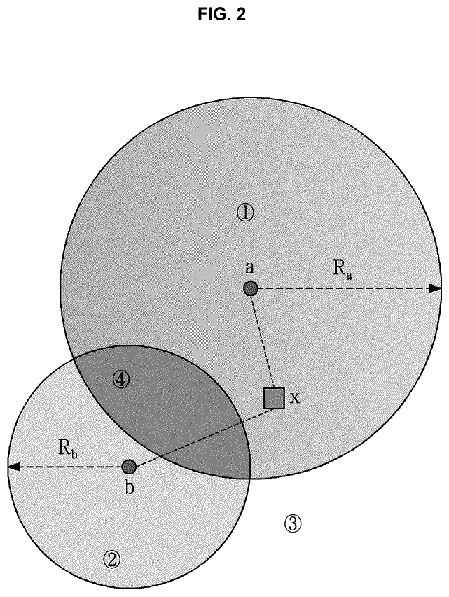

FIG. 2 is a schematic view illustrating the solubility range of each photoresist according to exposure energy by performing a simulation on a composition according to the present disclosure.

Referring to FIG. 2, regions of high solubility for unexposed portions are indicated as \textcircled{1} and \textcircled{4}, and regions of high solubility for exposed portions are indicated as \textcircled{2} and \textcircled{4}.

At this time, the region where the solubility for the unexposed portion high but the solubility for the exposed portion is low, and the difference in solubility between the unexposed portion and the exposed portion may be significantly or substantially contrasted, is the region indicated by \textcircled{1}, and the developer composition to be implemented in the present disclosure has the parameters of the region indicated by \textcircled{1}, and regions \textcircled{2}, \textcircled{3}, and \textcircled{4} may be defined as regions where the sensitivity is reduced or scum and bridges occur in contrast to region \textcircled{1}.

Meanwhile, the region \textcircled{3} refers to a region with low solubility for both (e.g., simultaneously) the unexposed portion and the exposed portion.

The developer composition for the metal-containing photoresist according to one or more embodiments may include at least one selected from among an ether, an alcohol, a glycol ether, an aromatic hydrocarbon compound, a ketone, and an ester, but embodiments of the present disclosure are not limited thereto. For example, the organic solvent may include ethylene glycol monomethyl ether, ethylene glycol monoethyl ether, methyl cellosolve acetate, ethyl cellosolve acetate, diethylene glycol methyl ether, diethylene glycol ethyl ether, propylene glycol, propylene glycol methyl ether (PGME), propylene glycol methyl ether acetate (PGMEA), propylene glycol ethyl ether, propylene glycol ethyl ether acetate, propylene glycol propyl ether acetate, propylene glycol butyl ether, propylene glycol butyl ether acetate, ethanol, propanol, isopropyl alcohol, isobutyl alcohol, 2-butanol, 4-methyl-2-pentanol (or may be referred to as methyl isobutyl carbinol (MIBC)), hexanol, 1-methoxy-2-propanol, 1-ethoxy-2-propanol, ethylene glycol, propylene glycol, heptanone, propylene carbonate, butylene carbonate, toluene, xylene, methyl ethyl ketone, cyclopentanone, cyclohexanone, 2-heptanone, acetylacetone, acetic acid, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, gamma-butyrolactone, methyl-2-hydroxyisobutyrate, methoxybenzene, n-butyl acetate, 1-methoxy-2-propyl acetate, methyl methoxy propionate, ethyl ethoxy propionate, or a mixture thereof, but embodiments of the present disclosure are not limited thereto.

The developer composition for a metal-containing photoresist according to one or more embodiments may further include at least one other additive selected from among an organic acid, a surfactant, a dispersant, a hygroscopic agent, and a coupling agent.

Meanwhile, according to one or more embodiments, a method of forming or providing patterns may include a developing method utilizing the developer composition for a metal-containing photoresist as described in one or more embodiments. For example, the manufactured pattern may be a negative-type or kind photoresist pattern.

A method for forming or providing patterns according to one or more embodiments may include coating a metal-containing photoresist composition on a substrate, performing heat treatment in which a metal-containing photoresist film is formed or provided on the substrate by drying and heating, exposing the metal-containing photoresist film, and developing utilizing the developer composition for the metal-containing photoresist.

For example, the forming or providing of the patterns utilizing the metal-containing photoresist composition may include coating a metal-containing photoresist composition on a substrate on which a thin film is formed or provided by spin coating, slit coating, inkjet printing, and/or the like, and drying the coated metal-containing photoresist composition to form or provide a resist layer.

The metal-containing photoresist composition may include an organometallic compound including at least one selected from an organic oxy group and an organic carbonyloxy group.

For example, the organometallic compound may include at least one metal selected from among tin (Sn), tellurium (Te), and antimony (Sb).

For example, the organometallic compound may include Sn.

In one or more embodiments, the metal-containing photoresist composition may include an organotin compound represented by Chemical Formula 1.

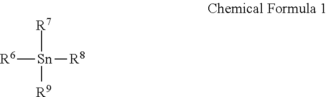

In Chemical Formula 1,
R⁶ may be selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group,
R⁷ to R⁹ may each independently be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, an alkoxy or aryloxy group (—OR^{b}, wherein R_{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido or dialkylamido group (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{h}C(NRⁱ)Rⁱ, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio or arylthiol group (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), or a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and
at least one selected from among R⁷ to R⁹ may be an alkoxy or aryloxy group (—OR^{b}, wherein R_{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido or dialkylamido group (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{h}C(NRⁱ)Rⁱ, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio or arylthiol group (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), or a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

For example, at least one selected from among R⁷ to R⁹ may be selected from an alkoxy or aryloxy group (—OR^{b}, wherein R_{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof) and a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

For example, R⁶ may be a substituted or unsubstituted C1 to C8 alkyl group, a substituted or unsubstituted C3 to C8 cycloalkyl group, a substituted or unsubstituted C2 to C8 aliphatic unsaturated organic group including one or more double bonds and/or triple bonds, a substituted or unsubstituted C6 to C20 aryl group, a substituted or unsubstituted C4 to C20 heteroaryl group, a carbonyl group, an ethoxy group, a propoxy group, or a combination thereof,
R_{b} may be a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof, and
R^{c} may be hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof.

In one or more embodiments, the metal-containing photoresist composition may include an organotin compound represented by Chemical Formula 2 or Chemical Formula 3.

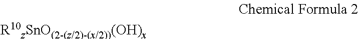

In Chemical Formula 2,
R¹⁰ may be a C1 to C31 hydrocarbyl group, 0<z≤2, and 0<(z+x)≤4;

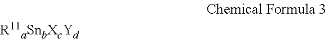

wherein, in Chemical Formula 3,
R¹¹ may be a substituted or unsubstituted C1 to C20 alkyl group, a substituted or unsubstituted C3 to C20 cycloalkyl group, a substituted or unsubstituted C2 to C20 aliphatic unsaturated organic group including one or more double bonds and/or triple bonds, a substituted or unsubstituted C6 to C30 aryl group, a substituted or unsubstituted C4 to C30 heteroaryl group, a carbonyl group, an ethylene oxide group, a propylene oxide group, or a combination thereof,
X may be sulfur(S), selenium (Se), or tellurium (Te),
Y may be —OR^{m} or —OC(═O)Rⁿ,
wherein R^{m} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
Rⁿ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
a, b, c, and d may each independently be an integer of 1 to 20.

Subsequently, a first heat treatment process may be performed to heat the substrate on which the metal-containing photoresist film is formed or provided. The first heat treatment process may be performed at a temperature of about 80° C. to about 120° C. In this process, the solvent may be evaporated and the metal-containing photoresist film may be more firmly or suitably adhered to the substrate.

Then, the photoresist film is selectively exposed.

Examples of light that may be used in the exposure process may include not only light having relatively low energy wavelengths, such as i-line (wavelength of 365 nm), KrF excimer laser (wavelength of 248 nm), and/or ArF excimer laser (wavelength of 193 nm), but also light having relatively high energy wavelengths, such as extreme ultraviolet (EUV, wavelength of 13.5 nm), and other sources, such as electron beam (e-beam) and/or the like.

For example, the light for exposure according to one or more embodiments may be light having relatively high energy wavelengths in a range of about 5 nm to about 150 nm, such as extreme ultraviolet (EUV, wavelength 13.5 nm), and other sources, such as electron beam (e-beam) and/or the like.

In the method of forming or providing the photoresist pattern, a negative-type or kind pattern may be formed or provided.

The exposed portion of the photoresist film may form or provide a polymer through a crosslinking reaction, such as condensation between organometallic compounds, and thus may have a different solubility from the unexposed portion of the photoresist film.

Then, a second heat treatment process may be performed on the substrate. The second heat treatment process may be performed at a temperature of about 90° C. to about 200° C. By performing the second heat treatment process, the exposed portion of the photoresist film may become difficult to be dissolved in a developer.

For example, the photoresist pattern corresponding to the negative-type or kind tone image may be completed by dissolving and then removing the photoresist film corresponding to the unexposed portion utilizing the photoresist developer as described in one or more embodiments.

As described in one or more embodiments, the photoresist pattern formed or provided by exposure to not only light having relatively low energy wavelengths, such as i-line (wavelength of 365 nm), KrF excimer laser (wavelength of 248 nm), and/or ArF excimer laser (wavelength of 193 nm), but also light having relatively high energy wavelengths, such as extreme ultraviolet (EUV; wavelength of 13.5 nm), and other sources, such as electron beam (e-beam), may have a thickness width of about 5 nm to about 100 nm. For example, the photoresist pattern may be formed or provided to have a thickness width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

In one or more embodiments, the photoresist pattern may have a pitch having a half-pitch of less than or equal to about 50 nm, for example, less than or equal to about 40 nm, for example, less than or equal to about 30 nm, for example, less than or equal to about 20 nm, for example, less than or equal to about 15 nm, and a line width roughness of less than or equal to about 10 nm, less than or equal to about 5 nm, less than or equal to about 3 nm, or less than or equal to about 2 nm.

Hereinafter, a method of forming or providing patterns is described in more detail with reference to the drawings.

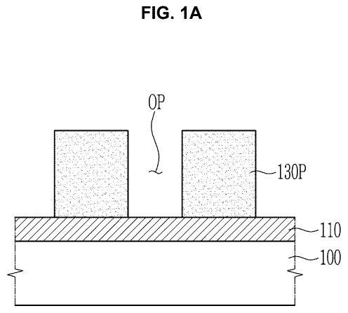

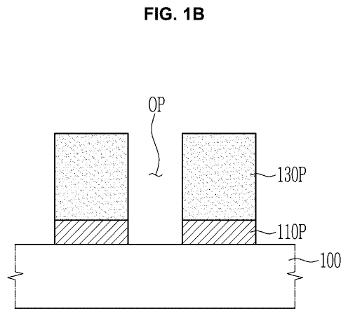

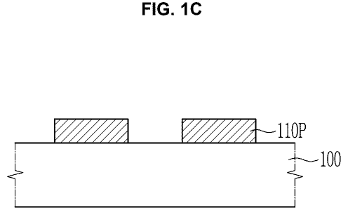

FIGS. 1A-1C are cross-sectional views illustrating a process sequence in order to describe a method of forming or providing patterns.

Referring to FIG. 1A, the exposed photoresist film may be developed to form or provide a photoresist pattern 130P.

In one or more embodiments, the exposed photoresist film may be developed to remove an unexposed portion of the photoresist film, and the photoresist pattern 130P including the exposed portion of the photoresist film may be formed or provided. The photoresist pattern 130P may include a plurality of openings OP.

In one or more embodiments, the development of the photoresist film may be performed through a negative-tone development (NTD) process. Herein, the developer composition for the metal-containing photoresist according to one or more embodiments may be utilized as a developer composition.

Referring to FIG. 1B, the photoresist pattern 130P may be utilized to process a feature layer 110 in the result of FIG. 1A.

For example, the feature layer 110 may be processed through one or more suitable processes of etching a feature layer 110 exposed through the openings OP of the photoresist pattern 130P, injecting impurity ions into the feature layer 110, forming or providing an additional film on the feature layer 110 through the openings OP, deforming a portion of the feature layer 110 through the openings OP, and/or the like. FIG. 1B illustrates a method of processing a feature pattern 110P by etching the feature layer 110 exposed through the openings OP.

Referring to FIG. 1C, the photoresist pattern 130P remaining on the feature pattern 110P may be removed in the result of FIG. 2. In order to remove the photoresist pattern 130P, ashing and stripping processes may be utilized. The feature pattern 110P may be on a substrate 100.

Hereinafter, one or more embodiments of the present disclosure will be described in more detail through examples relating to the preparation of the developer composition for the metal-containing photoresist as described in one or more embodiments. However, embodiments of the present disclosure are not limited by the following examples.

### EXAMPLES

An organometallic compound (a cluster of 21 Sn molecules ((t-Bu)₃Sn₃(O₂CH)₅(OH)₂O) was dissolved in propylene glycol methyl ether acetate (PGMEA) at a concentration of 3% and then, filtered with a 0.1 μm polytetrafluoroethylene (PTFE) syringe filter to prepare a semiconductor photoresist composition, which was spin-coated on an 8-inch wafer at 1,500 rpm for 30 seconds and then, heat-treated at 160° C. for 60 seconds to manufacture a coated wafer. The coated wafer was subjected to KrF exposure and post-exposure bake (PEB) processes step by step within an exposure energy range of 7 mJ/cm² to 25 mJ/cm².

Subsequently, a development process was performed for each exposure energy method (e.g., step) by a developer composition including a corresponding solvent as shown in Table 1 to manufacture a film with a pattern formed or provided thereon, and the dissolved film was measured with respect to a thickness, which was used to obtain a relative thickness (a thickness of the developed photoresist film after exposure with second exposure energy/a thickness of the developed photoresist film after exposure with first exposure energy) expressed as a contrast curve, and after classifying a film thickness of less than or equal to 20% as soluble but a film thickness of greater than 20% as insoluble from the contrast curve to obtain data of dissolubility for at least 5 solvents, the data were used to calculate an HSP sphere. The Hansen solubility parameter simulation, which used a methodology presented in the paper “Calculating Hansen solubility parameters of polymers with genetic algorithms” G. Cañete Vebber, et al., J. Appl. Polym. Sci., 2014, was performed by fitting the data to maximize or increase the solubility scores, obtaining a solubility factors and dissolvable radiuses Rₐ and R_{b} of the photoresist and thereby, obtain ranges satisfying the relationship of x̅ a̅<Rₐ and x̅ b̅>R_{b}.

TABLE 1

| | | Simulation result | | | | | | | |
|---|---|---|---|---|---|---|---|---|---|
| | Developer | | | | | | x̅ a̅ < | x̅ b̅ > | |
| | composition | δd | δp | δh | x̅ a̅ | x̅ b̅ | Rₐ | R_{b} | Region |
| Example 1 | S1 | 16.1 | 10.0 | 6.2 | 10.9 | 8.3 | True | True | \textcircled{1} |
| Example 2 | S2 | 15.7 | 6.3 | 8.8 | 13.0 | 4.9 | True | True | \textcircled{1} |
| Example 3 | S3 | 15.8 | 6.7 | 8.5 | 12.7 | 5.2 | True | True | \textcircled{1} |
| Example 4 | S4 | 16.0 | 8.8 | 7.1 | 11.4 | 7.0 | True | True | \textcircled{1} |
| Example 5 | S5 | 18.0 | 16.6 | 7.4 | 10.4 | 12.8 | True | True | \textcircled{1} |
| Example 6 | S6 | 17.6 | 15.3 | 7.2 | 10.0 | 11.6 | True | True | \textcircled{1} |
| Comparative | S7 | 15.7 | 5.9 | 9.0 | 13.3 | 4.6 | False | True | \textcircled{3} |
| Example 1 | | | | | | | | | |
| Comparative | S8 | 14.5 | 8.0 | 13.5 | 10.9 | 3.3 | True | False | \textcircled{4} |
| Example 2 | | | | | | | | | |
| Comparative | S9 | 15.8 | 3.7 | 6.3 | 15.8 | 7.8 | False | True | \textcircled{3} |
| Example 3 | | | | | | | | | |
| Comparative | S10 | 15.5 | 4.1 | 12.7 | 14.9 | 2.5 | False | False | \textcircled{2} |
| Example 4 | | | | | | | | | |
| Comparative | S11 | 14.5 | 8.0 | 13.4 | 11.0 | 3.2 | True | False | \textcircled{4} |
| Example 5 | | | | | | | | | |
| Comparative | S12 | 15.0 | 7.2 | 11.7 | 11.6 | 2.8 | True | False | \textcircled{4} |
| Example 6 | | | | | | | | | |
| Comparative | S13 | 16.2 | 5.7 | 4.1 | 15.1 | 9.6 | False | True | \textcircled{3} |
| Example 7 | | | | | | | | | |
| Comparative | S14 | 15.8 | 5.7 | 14.5 | 14.1 | 1.0 | False | False | \textcircled{2} |
| Example 8 | | | | | | | | | |
| Comparative | S15 | 17.8 | 4.4 | 6.9 | 16.9 | 8.0 | False | True | \textcircled{3} |
| Example 9 | | | | | | | | | |

Developer Composition
S1: Acetylacetone (AcAc)
S2: Propylene glycol methyl ether acetate (PGMEA)/AcAc = 90/10 (wt %/wt %)
S3: Propylene glycol methyl ether acetate (PGMEA)/AcAc = 80/20 (wt %/wt %)
S4: Propylene glycol methyl ether acetate (PGMEA)/AcAc = 70/30 (wt %/wt %)
S5: Gamma-butyrolactone (GBL)
S6: GBL/AcAc = 80/20 (wt %/wt %)
S7: PGMEA
S8: Acetic acid (AA)
S9: n-Butyl acetate
S10: Methyl isobutyl carbinol (MIBC)
S11: PGMEA/AA = 98/2 (wt %/wt %)
S12: PGMEA/AA = 60/40 (wt %/wt %)
S13: 2-Heptanone
S14: 2-Butanol
S15: Anisole (or methoxybenzene)

### Evaluation: Sensitivity/Scum and Bridge Evaluation

The prepared composition for an organic metal-containing semiconductor photoresist was spin-coated on an 8-inch wafer at 1,500 rpm for 30 seconds and then, heat-treated at 160° C. for 60 seconds to manufacture a coated wafer.

Subsequently, a liner array of 50 circular pads with a diameter of 500 μm was projected onto the wafer coated with the developer composition for a photoresist by using EUV light (Lawrence Berkeley National Laboratory Micro Exposure Tool, MET). The pad exposure time was controlled, so that EUV at an increasing dose was applied to each pad.

Subsequently, the resist and the substrate were exposed at 160° C. on a hot plate for 120 seconds and then, baked. The baked film was developed by applying each of the developer compositions of Examples 1 to 6 and Comparative Examples 1 to 9 at a spin speed of 1,500 rpm for 30 seconds and then, cured at 240° C. for 60 seconds.

As a result, a L/S (=1:1) pattern with a line width of 50 nm was formed or provided.

An optimal exposure dose of Eop (μC/cm²) to form or provide a LS pattern with a target size was obtained.

When a space dimension was decreased by reducing an irradiation dose from the optimal exposure dose of Eop (μC/cm²), a minimum dose to form or provide a pattern without a defect, such as scum, bridge, and/or the like was defined as E₀, which is shown in Table 2.

A resist line width for an exposure dose (Energy) change was measured by using CD-SEM. Each different resist line width depending on each exposure dose was used to check appropriate sensitivity E_{gel} for the exposure dose. Also, the CD-SEM image was used to check a degree to which the scum and bridge were formed, and the results are shown in Table 2.

TABLE 2

| | E₀ | E_{gel} | Scum | Bridge |
|---|---|---|---|---|
| Example 1 | 11 | 20 | No | No |
| Example 2 | 8 | 16 | No | No |
| Example 3 | 10 | 16 | No | No |
| Example 4 | 11 | 20 | No | No |
| Example 5 | 12 | 16 | No | No |
| Example 6 | 12 | 18 | No | No |
| Comparative Example 1 | 5 | 15 | Occur | Occur |
| Comparative Example 2 | 40 | >55 | No | Occur |
| Comparative Example 3 | <5 | 13 | Occur | Occur |
| Comparative Example 4 | 16 | 19 | Occur | Occur |
| Comparative Example 5 | 15 | 29 | No | Occur |
| Comparative Example 6 | 35 | >55 | No | Occur |
| Comparative Example 7 | 10 | 16 | Occur | Occur |
| Comparative Example 8 | 22 | 23 | Occur | Occur |
| Comparative Example 9 | <5 | 12 | Occur | Occur |

Referring to Table 2, in Examples 1 to 6, E₀ and E_{gel} were lowered and the sensitivity was improved or enhanced, while scum and bridge occurrence were not observed.

Hereinbefore, certain embodiments of the present disclosure have been described and illustrated, however, it should be apparent to a person having ordinary skill in the art that the present disclosure is not limited to the embodiments as described, and may be suitably modified and transformed without departing from the spirit and scope of the present disclosure. Accordingly, the modified or transformed embodiments as such may not be understood separately from the technical ideas and aspects of embodiments of the present disclosure, and the modified embodiments may be within the scope of the appended claims and equivalents thereof of the present disclosure.

### REFERENCE NUMERALS

| | |
|---|---|
| 100: substrate | OP: opening |
| 110: feature layer | 110P: feature pattern |
| 130P: photoresist pattern | |

What is claimed is:

1. A developer composition for a metal-containing photoresist,
wherein the developer composition is applied to the metal-containing photoresist,
a coordinate a is specified by the Hansen solubility parameters (δd, δp, and δh) of a first photoresist exposed to the metal-containing photoresist with a first exposure energy of 9 to 12 mJ/cm²;
a coordinate b is specified by the Hansen solubility parameters (δd, δp, and δh) of a second photoresist exposed to the metal-containing photoresist with a second exposure energy that is 5 to 10 mJ/cm² higher than the first exposure energy; and
for a coordinate x which is specified by the Hansen solubility parameters (δd, δp, and δh) of the developer composition,
a solubility radius Rₐ with the coordinate a as a center value is calculated,
a solubility radius R_{b} with the coordinate b as an other center value is calculated, and
a distance (x̅ a̅) between the coordinate x and the coordinate a and a distance (x̅ b̅) between the coordinate x and the coordinate b, which are calculated by Equation 1 and Equation 2, respectively, have the relationships x̅ a̅<Rₐ and x̅ b̅>R_{b};
$$\overline{x {a}^{2}} = 4 {( δ {d}_{x} - δ {d}_{a} )}^{2} + {( δ {p}_{x} - δ {p}_{a} )}^{2} + {( δ {h}_{x} - δ {h}_{a} )}^{2} \qquad Equation 1$$
$$\overline{x {b}^{2}} = 4 {( δ {d}_{x} - δ {d}_{b} )}^{2} + {( δ {p}_{x} - δ {p}_{b} )}^{2} + {( δ {h}_{x} - δ {h}_{b} )}^{2} . \qquad Equation 2$$

2. The developer composition for a metal-containing photoresist as claimed in claim 1, wherein:
the developer composition comprises ethylene glycol monomethyl ether, ethylene glycol monoethyl ether, methyl cellosolve acetate, ethyl cellosolve acetate, diethylene glycol methyl ether, diethylene glycol ethyl ether, propylene glycol, propylene glycol methyl ether (PGME), propylene glycol methyl ether acetate (PGMEA), propylene glycol ethyl ether, propylene glycol ethyl ether acetate, propylene glycol propyl ether acetate, propylene glycol butyl ether, propylene glycol butyl ether acetate, ethanol, propanol, isopropyl alcohol, isobutyl alcohol, 2-butanol, 4-methyl-2-pentanol, hexanol, 1-methoxy-2-propanol, 1-ethoxy-2-propanol, ethylene glycol, propylene glycol, heptanone, propylene carbonate, butylene carbonate, toluene, xylene, methyl ethyl ketone, cyclopentanone, cyclohexanone, 2-heptanone, acetylacetone, acetic acid, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, gamma-butyrolactone, methyl-2-hydroxyisobutyrate, methoxybenzene, n-butyl acetate, 1-methoxy-2-propyl acetate, methyl methoxy propionate, ethyl ethoxy propionate, or a mixture thereof.

3. The developer composition for a metal-containing photoresist as claimed in claim 1, wherein:
the developer composition comprises acetylacetone, propylene glycol methyl ether acetate, gamma-butyrolactone, acetic acid, n-butyl acetate, methyl isobutyl carbinol, 2-heptanone, 2-butanol, methoxybenzene, or a combination thereof.

4. The developer composition for a metal-containing photoresist as claimed in claim 2, wherein:
the developer composition further comprises at least one additive selected from among an organic acid, a surfactant, a dispersant, a hygroscopic agent, and a coupling agent.

5. A method of forming patterns, comprising:
coating a metal-containing photoresist composition on a substrate;
performing heat treatment in which a metal-containing photoresist film is on the substrate by drying and heating;
exposing the metal-containing photoresist film; and
developing utilizing the developer composition for the metal-containing photoresist as claimed in claim 1.

6. The method as claimed in claim 5, wherein:
the metal-containing photoresist composition comprises an organometallic compound comprising at least one selected from an organic oxy group and an organic carbonyloxy group.

7. The method as claimed in claim 6, wherein:
the organometallic compound comprises at least one metal selected from among Sn, Te, and Sb.

8. The method as claimed in claim 6, wherein:
the organometallic compound comprises Sn.

9. The method as claimed in claim 5, wherein:
the metal-containing photoresist composition comprises an organotin compound represented by Chemical Formula 1: 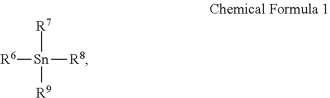
wherein, in Chemical Formula 1,
R⁶ is selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group,
R⁷ to R⁹ are each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, an alkoxy or aryloxy group (—OR^{b}, wherein R_{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido or dialkylamido group (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{h}C(NRⁱ)Rⁱ, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio or arylthiol group (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), or a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and
at least one selected from among R⁷ to R⁹ is an alkoxy or aryloxy group (—OR^{b}, wherein R_{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido or dialkylamido group (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{h}C(NRⁱ)Rⁱ, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio or arylthiol group (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), or a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

10. The method as claimed in claim 9, wherein:
at least one selected from among R⁷ to R⁹ is selected from among an alkoxy or aryloxy group (—OR^{b}, wherein R_{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof) and a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

11. The method as claimed in claim 7, wherein:
R⁶ is a substituted or unsubstituted C1 to C8 alkyl group, a substituted or unsubstituted C3 to C8 cycloalkyl group, a substituted or unsubstituted C2 to C8 aliphatic unsaturated organic group comprising one or more double bonds or triple bonds, a substituted or unsubstituted C6 to C20 aryl group, a substituted or unsubstituted C4 to C20 heteroaryl group, a carbonyl group, an ethoxy group, a propoxy group, or a combination thereof,
R_{b} is a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof, and
R^{c} is hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof.

12. The method as claimed in claim 5, wherein:
the metal-containing photoresist composition comprises an organotin compound represented by Chemical Formula 2 or Chemical Formula 3: 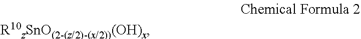
wherein, in Chemical Formula 2,
R¹⁰ is a C1 to C31 hydrocarbyl group, 0<z≤2, and 0< (z+x)≤4; 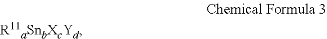
wherein, in Chemical Formula 3,
R¹¹ is a substituted or unsubstituted C1 to C20 alkyl group, a substituted or unsubstituted C3 to C20 cycloalkyl group, a substituted or unsubstituted C2 to C20 aliphatic unsaturated organic group comprising one or more double bonds or triple bonds, a substituted or unsubstituted C6 to C30 aryl group, a substituted or unsubstituted C4 to C30 heteroaryl group, a carbonyl group, an ethylene oxide group, a propylene oxide group, or a combination thereof,
X is sulfur(S), selenium (Se), or tellurium (Te),
Y is —OR^{m} or —OC(═O)Rⁿ,
wherein R^{m} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
Rⁿ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
a, b, c, and d are each independently an integer of 1 to 20.

13. The method as claimed in claim 5, wherein:
the patterns are a negative-type pattern.

14. The method as claimed in claim 5, wherein:
the patterns have a thickness width of 5 nm to 100 nm.

15. The method as claimed in claim 5, wherein:
the patterns have a pitch having a half-pitch of less than or equal to 50 nm.

16. The method as claimed in claim 5, wherein:
the patterns have a line width roughness of less than or equal to 10 nm.

17. The method as claimed in claim 5, wherein:
the performing of the heat treatment comprises a first heat treatment at a temperature of 80° C. to 120° C.

18. The method as claimed in claim 5, wherein:
the performing of the heat treatment comprises a second heat treatment at a temperature of 90° C. to 200° C.

19. The method as claimed in claim 5, wherein:
the exposing of the metal-containing photoresist film is exposing the metal-containing photoresist film to light having a wavelength in a range of 5 nm to 150 nm.

20. The method as claimed in claim 5, wherein:
the exposing of the metal-containing photoresist film is exposing the metal-containing photoresist film to i-line, KrF excimer laser, ArF excimer laser, extreme ultraviolet, electron beam, or a combination thereof.
